(19) United States
(12) Patent Application Publication
(10) Pub. No.: US 2011/0050251 A1
(43) Pub. Date: Mar. 3, 2011

(54) Capacitive sensor and actuator

(76) Inventors: Axel FRANKE, Ditzingen (DE); Alexander Buhmann, Stuttgart (DE); Marian Keck, Leonberg (DE)

(21) Appl. No.: 12/846,314

(22) Filed: Jul. 29, 2010

(30) Foreign Application Priority Data
Aug. 27, 2009 (DE) 102009028924.0

(51) Int. Cl. G01R 27/26

(52) U.S. Cl. 324/658

(57) ABSTRACT

A capacitive sensor and a capacitive actuator having at least one seismic mass deflectably mounted on a substrate. A comb electrode having comb fingers is mounted on the seismic mass, and a comb electrode having comb fingers is mounted on the substrate in such a way that the comb fingers are situated parallel to a deflection direction of the seismic mass and interlock in a comb-like manner. The characteristic curve of the sensor or actuator is adjusted by optimizing the geometry of at least one comb electrode, in particular of at least one comb finger.

### FIELD OF THE INVENTION

The present invention relates to a capacitive sensor and actuator having at least one seismic mass deflectably mounted on a substrate, a comb electrode having comb fingers being mounted on the seismic mass, and a comb electrode having comb fingers being mounted on the substrate, and the comb fingers being situated parallel to a direction of the deflection of the seismic mass and interlocking in a comb-like manner.

### BACKGROUND INFORMATION

Sensors are known in many fields of technology. Micromechanical sensors are used, for example, in automotive, industrial, and medical technology, as well as in many areas of consumer electronics, in particular as acceleration, rotational speed, or pressure sensors. Capacitive sensors in particular are widely used.

Capacitive sensors are based on a spring-mass system in which a seismic mass is deflected with respect to a substrate, against a predetermined restoring force, for example as the result of acceleration or pressure forces which occur. Electrodes which are connected to the seismic mass and electrodes which are mounted on the substrate form a capacitor. In particular, the size of the overlap area of the electrodes is changed as a result of the deflection of the seismic mass with respect to the substrate, and thus the deflection of the electrodes relative to one another. This motion, i.e., deflection, of the electrodes has an influence on the capacitance of the capacitor formed by the electrodes, since the capacitance changes in particular as a function of the size of the overlap area of the electrodes as well as the distance between the electrodes.

Capacitive sensors are therefore based on the change in capacitance of a capacitor or a plurality of capacitors caused by the motion of the electrodes relative to one another. The change in the capacitance may be easily evaluated electrically, and thus allows computation of the force, for example acceleration or pressure, which occurs.

Such a system may also be used as an actuator. In contrast to a sensor, which is used to detect motion, an actuator is suitable for generating electrostatic forces and actuator travel. For this purpose a voltage is applied to the capacitor, which generates an electrostatic force and moves the electrodes relative to one another, thus achieving an actuator travel of the electrodes or of the components attached to the electrodes.

It is known to use so-called comb electrodes for designing a capacitive sensor or actuator. These electrodes are formed by comb fingers of individual electrodes which interlock in a comb-like manner, forming a system of multiple plate capacitors. Plate capacitors and thus comb electrodes have the property of having a nonlinear characteristic curve which is described by the transfer function between electrical voltage and electrostatic force, i.e., deflection. Such a nonlinear characteristic curve may be desired in obtaining, with regard to the rate of deflection, high sensitivity for small deflections and low sensitivity for large deflections. However, for plate capacitors of the related art the shape of the characteristic curve is strictly specified, so that the dynamic range is severely limited.

In addition, it is often desired to achieve linear dependencies between the electrical voltage and the deflection. The use of differential capacitors is known to achieve this. A differential capacitor is composed essentially of two plate capacitors having a shared middle electrode. In this case the middle electrode is used as a movable seismic mass. When the middle electrode moves relative to the two adjacent outer electrodes, the capacitance of the two capacitors changes, as described above. It is a characteristic of differential capacitors that the characteristic curve may be linearized due to the parallel structure of the plate capacitors.

However, a disadvantage of such differential capacitors is that additional electrodes are required, which is objectionable in particular for sensors or actuators in the field of micromechanics since the required dimensioning is difficult to achieve.

### SUMMARY OF THE INVENTION

The subject matter of the present invention is a capacitive sensor and a capacitive actuator having at least one seismic mass deflectably mounted on a substrate, a comb electrode having comb fingers being mounted on the seismic mass, and a comb electrode having comb fingers being mounted on the substrate, and the comb fingers being situated parallel to a direction of the deflection of the seismic mass and interlocking in a comb-like manner, and the characteristic curve of the sensor and of the actuator being adjusted by optimizing the geometry of at least one comb electrode, in particular of at least one comb finger.

Due to the fact that the characteristic curve of the sensor or of the actuator is adjusted by optimizing the geometry of at least one comb electrode, in particular of at least one comb finger, the shape of the characteristic curve may be selected as desired by using specially optimized comb fingers in a comb electrode. It is thus possible on the one hand to adjust the dynamic range of a nonlinear characteristic curve and to increase the dynamic range as desired. Adjustment to various acting forces or evaluation systems, for example, may be achieved in this way.

On the other hand, it is also possible to linearize the characteristic curve, which is often desired. A linearized characteristic curve is advantageous, in particular for an actuator according to the present invention. When a voltage is applied to the capacitor, the resulting force and thus the deflection or the actuator travel follows a linear curve, which greatly simplifies the use of the actuator according to the present invention.

For the sensor according to the present invention as well as the actuator according to the present invention, as a result of optimizing the geometry in particular of at least one comb finger, the characteristic curve conforms to a desired transfer function. The design of this function and thus the geometric optimization is achieved on the basis of the required task, namely, adjusting the linearity or a dynamic range.

Sensors and actuators according to the present invention may have very compact designs, so that they may be easily used as micromechanical sensors and actuators.

In one specific embodiment of the present invention, the geometry of the at least one comb electrode is optimized via a predetermined height profile of the at least one comb finger. This specific embodiment may be adapted in a particularly precise manner to the task in question.

It is particularly advantageous when the height profile is produced by applying insulation. Thus, commercially available comb fingers which are provided with insulation may be used in order to subdivide the comb fingers along the predetermined height profile into an area which is active for the capacitance and an area which is inactive for the capacitance. “Applying insulation” means any process to make a certain area of a comb finger inactive with regard to the capacitance by providing insulation.

In a further specific embodiment of the present invention, the geometry of the at least one comb electrode is optimized via a predetermined length profile of the at least one comb finger. This specific embodiment may be manufactured in a particularly simple manner.

In a further specific embodiment of the present invention, the geometry of the at least one comb electrode is optimized via a predetermined distance profile of the at least one comb finger. Good results may also be achieved in this manner.

### BRIEF DESCRIPTION OF THE DRAWINGS

FIG. 1 shows a top view of one specific embodiment of the capacitive sensor or actuator according to the present invention.

FIG. 2 shows a side view of the capacitive sensor or actuator according to FIG. 1, along line A-A′.

FIG. 3 shows a top view of another specific embodiment of the capacitive sensor or actuator according to the present invention.

FIG. 4 shows a side view of the capacitive sensor or actuator according to FIG. 3, along line B-B′.

FIG. 5 shows a top view of another specific embodiment of the capacitive sensor or actuator according to the present invention.

### DETAILED DESCRIPTION

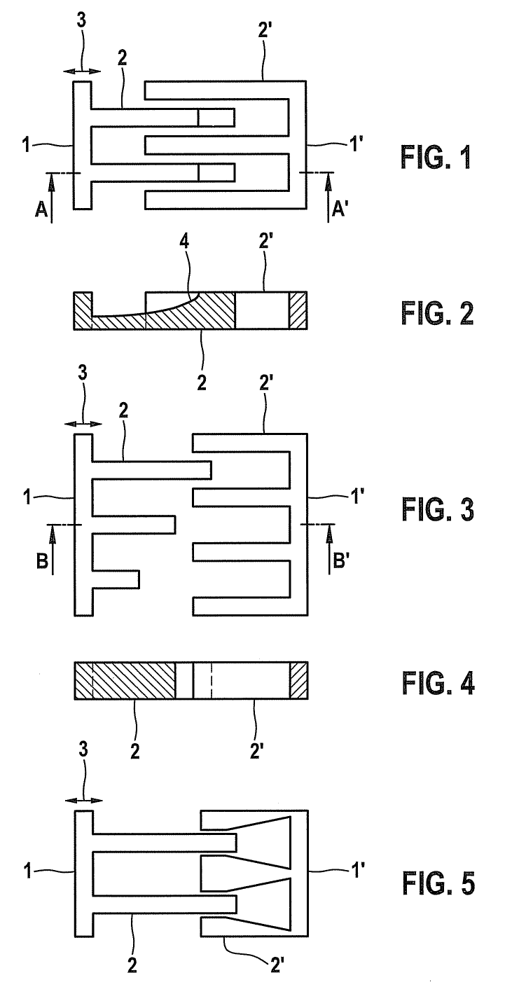

The capacitive sensor according to FIG. 1 includes a seismic mass (not illustrated) which is deflectably mounted on an immovable substrate, or possibly mounted on an additional movable mass. The deflectability of the seismic mass may be achieved, for example, by mounting the seismic mass on the substrate, using one spring or multiple springs having a defined stiffness. A first comb electrode 1 having multiple comb fingers 2 is also mounted on the seismic mass, and a second comb electrode 1′ having multiple comb fingers 2′ is mounted on the substrate or the additional movable mass. Comb fingers 2 and 2′ of comb electrodes 1 and 1′, respectively, are aligned in parallel, and interlock in a comb-like manner in such a way that in the neutral state they form an overlap area. Comb fingers 2 and 2′ thus form a capacitor, the overlap surface being the effective surface area for the capacitance of the capacitor.

Comb electrodes 1 and 1′ are also mounted on the seismic mass or the substrate and aligned in such a way that comb fingers 2 and 2′ extend parallel to the direction of deflection of the seismic mass. When a force, for example an acceleration or pressure force, acts on the seismic mass, the seismic mass is deflected relative to the substrate, causing comb electrode 1 together with comb fingers 2 to move in one of the directions indicated by double arrow 3. The overlap area formed by comb fingers 2 and 2′ changes as a result of comb fingers 2 which thus move parallel to comb fingers 2′. This directly results in a change in the capacitance of the capacitor formed by comb fingers 2 and 2′. The change in capacitance caused by the acting force may be electrically evaluated, and the acting force may thus be computed.

The transfer function of the electrical voltage and of the force or the deflection describes a fixed characteristic curve which is a function of the capacitance of the capacitor, and thus of the distance between the electrodes and the overlap area thereof. According to the present invention, the geometry of at least one comb finger 2 or 2′, preferably of multiple comb fingers 2, is optimized; the following description relates essentially only to the optimization of multiple comb fingers without being limiting. This optimization of the geometry changes the distance between the electrodes and the overlap area thereof in order to adjust the capacitance of the capacitor and thus the transfer function. In this way the transfer function, i.e., the characteristic curve, may assume a desired shape, which means that the desired degree of the electrically measurable change in capacitance is a function of the acting force and thus of the deflection. The capacitive sensor according to the present invention may thus be easily adapted to various tasks.

FIG. 2 shows a first specific embodiment of the present invention. According to FIG. 2, the geometry of comb electrodes 1, in particular of comb fingers 2, is optimized via a predetermined height profile 4. As a result of this specific height profile 4, comb fingers 2 have a height with respect to comb fingers 2′ which varies as a function of the degree of the deflection. The height of comb electrode 1, similarly as its length, naturally influences the overlap area of the two electrode fingers 2, 2′, and thus influences the effective surface area for the capacitance. As a result of the deflection of the comb electrode, the overlap surface of comb fingers 2 and 2′ changes with respect to not only the length of comb fingers 2, 2′, but also their height. This further variable makes it possible according to the present invention to control the capacitance during the deflection of comb electrode 1, and thus to adjust the transfer function, i.e., the characteristic curve, as desired.

The dynamic range for a nonlinear characteristic curve may be greatly increased in comparison to the approaches known from the related art. For a small deflection a high sensitivity may thus be achieved, whereas for a large deflection the sensitivity may be selected to be less, and to a desired degree. Thus, by using a sensor according to the present invention the dynamic range may be precisely adapted to the intended field of application.

This applies not only to adjusting a desired dynamic range, but also to linearizing the transfer function, i.e., the characteristic curve. A linear characteristic curve of capacitive sensors is desired for many applications. Because the electrostatic force, or deflection, is a quadratic function of the voltage, the characteristic curve may be linearized in particular when height profile 4 of comb electrodes 1 is optimized according to the present invention in such a way that the quadratic voltage and the change in capacitance are increased. Since according to the present invention the change in specific height profile 4 of the overlap area of the electrodes, and thus the change in the effective surface area, is different from that of a comb finger of similar height due to the variable height of comb fingers 2, the quadratic increase may be compensated for by the selection of the height profile. By customizing the shape of height profile 4 it is thus possible to achieve a linear dependency of the force or the deflection and the voltage, and thus to linearize the characteristic curve.

The effect described above is similarly possible not by optimizing the height of comb fingers 2 per se, but, rather, by the comb fingers acquiring an area which is inactive for the capacitance by applying insulation. Height profile 4 is then produced by the targeted application of insulation, thus likewise allowing the effects described above to be achieved.

Another specific embodiment of the present invention is shown in FIGS. 3 and 4. The geometry of the at least one comb electrode 1 or 1′ is optimized via a predetermined length profile of the at least one comb finger 2 or 2′. According to FIG. 3, the length of three adjacent comb fingers 2 is optimized in such a way that the comb fingers have a stepped structure with regard to their length. This may be achieved, for example, by having the length of comb fingers 2 follow a Heaviside function, which allows the mathematical description of steps or thresholds. By customizing the shape of this longitudinal structure, a linear dependency of the applied voltage and of the electrostatic force or of the deflection may be produced, or the characteristic curve may be linearized. For this purpose, as also described with reference to FIG. 2, by using the specific length profile of comb fingers 2 the overlap area of the electrodes, and thus the effective surface area for the capacitance in the case of a deflection of the electrode, may be changed to a certain degree.

In this specific embodiment it is also possible to provide the length profile by applying insulation, as has been described for the height profile.

In addition to linearizing the characteristic curve, it is also possible to maintain the nonlinear shape of the characteristic curve and change only the dynamic range in the desired manner by adjusting the longitudinal structure of comb fingers 2. For this purpose a specific length profile must be suitably selected.

Another specific embodiment of the present invention is shown in FIG. 5.

According to FIG. 5, the capacitance is not adjusted by optimizing the overlap area, as described in FIGS. 2 and 3. Instead, in this specific embodiment use is made of the fact that the capacitance in the vicinity of the overlap area is likewise a function of the distance between the electrodes, the electrode gap.

In the specific embodiment according to FIG. 5, comb fingers 2′ have a wedge-shaped design at their end facing away from comb electrode 1, a pointed end facing away from comb electrode 1. When comb electrode 1 is deflected, the distance between comb electrodes 2 and 2′ thus changes. The change in the capacitance during a deflection may thus be adjusted as desired. Thus, in this case, by adjusting the distance profile, as also described with reference to FIG. 2, the quadratic increase in the electrostatic force with respect to the voltage may be compensated for in a sensor. Thus, according to FIG. 5, by customizing the shape of the distance profile a linear dependency of the applied voltage and of the resulting electrostatic force or of the deflection may be achieved and the characteristic curve may be linearized.

In addition to linearizing the characteristic curve, it is also possible to maintain the nonlinear shape of the characteristic curve and change only the dynamic range by adjusting the distance profile of comb fingers 2, as previously described.

In principle, it is possible to optimize the geometry of the comb fingers for a single comb finger 2 of comb electrode 1, as well as for a single comb finger 2′ of comb electrode 1′. However, it is more advantageous to optimize the geometry of multiple comb fingers 2 or 2′. Likewise, it is also possible to optimize only comb finger 2 of comb electrode 1, or to optimize only comb finger 2′ of comb electrode 1′, or to optimize both comb finger 2 and comb finger 2′. The optimized comb fingers and the number thereof may be selected based on the intended task and the intensity of the desired effects.

It is also possible within the scope of the present invention to optimize the geometry of comb fingers 2 only via the height profile, length profile, or distance profile, or to select suitable combinations of the geometric optimization.

In addition to a sensor, the concept according to the present invention may likewise be used for a capacitive actuator, since a capacitive actuator is the transducer-related counterpart to a capacitive sensor. The capacitive actuator according to the present invention has a design which is similar to the sensor according to the present invention. The capacitive actuator includes two comb electrodes 1 and 1′ having comb fingers 2 and 2′, respectively, comb fingers 2 and 2′ being aligned parallel to deflection direction 3 and interlocking in a comb-like manner in such a way that they form a capacitor in an overlap area. Comb electrode 1 is preferably mounted on a movable mass, while comb electrode 1′ is mounted on a fixed substrate.

When a voltage is applied to the capacitor, an electrostatic force is generated which moves the deflectable electrode. This deflection results in an actuator travel which may be controlled via the applied voltage. However, this deflection increases more than linear due to quadratic dependency of the electrostatic force from the voltage. To prevent this and to provide linearization of the characteristic curve, according to the present invention the geometry of at least one comb electrode 2 and/or 2′ may be optimized in such a way that the quadratic voltage and the change in capacitance increase. By optimizing the electrode geometry it is also possible to control the dynamic range of the nonlinear characteristic curve as desired, as previously described.

According to the present invention, this optimization is achieved by varying the height profile, length profile, and/or distance profile as described with regard to the sensor according to the present invention.

What is claimed is:

1. A capacitive sensor comprising:
a substrate;
at least one seismic mass deflectably mounted on the substrate;
a first comb electrode having first comb fingers mounted on the seismic mass; and
a second comb electrode having second comb fingers mounted on the substrate,
wherein the first and second comb fingers are situated parallel to a deflection direction of the seismic mass and interlock in a comb-like manner, and
wherein a characteristic curve of the sensor is adjusted by optimizing a geometry of at least one of the first and second comb electrodes.

2. The capacitive sensor according to claim 1, wherein the characteristic curve of the sensor is adjusted by optimizing a geometry of at least one of the first and second comb fingers.

3. The capacitive sensor according to claim 1, wherein the geometry of the at least one of the first and second comb electrodes is optimized via a predetermined height profile of at least one of the first and second comb fingers.

4. The capacitive sensor according to claim 3, wherein the height profile is produced by applying insulation.

5. The capacitive sensor according to claim 1, wherein the geometry of the at least one of the first and second comb electrodes is optimized via a predetermined length profile of at least one of the first and second comb fingers.

6. The capacitive sensor according to claim 1, wherein the geometry of the at least one of the first and second comb electrodes is optimized via a predetermined distance profile of at least one of the first and second comb fingers.

7. A capacitive actuator comprising:
a substrate;
at least one seismic mass deflectably mounted on the substrate;
a first comb electrode having first comb fingers mounted on the seismic mass; and
a second comb electrode having second comb fingers mounted on the substrate,
wherein the first and second comb fingers are situated parallel to a deflection direction of the seismic mass and interlock in a comb-like manner, and
wherein a characteristic curve of the actuator is adjusted by optimizing a geometry of at least one of the first and second comb electrodes.

8. The capacitive actuator according to claim 7, wherein the characteristic curve of the actuator is adjusted by optimizing a geometry of at least one of the first and second comb fingers.

9. The capacitive actuator according to claim 7, wherein the geometry of the at least one of the first and second comb electrodes is optimized via a predetermined height profile of at least one of the first and second comb fingers.

10. The capacitive actuator according to claim 9, wherein the height profile is produced by applying insulation.

11. The capacitive actuator according to claim 7, wherein the geometry of the at least one of the first and second comb electrodes is optimized via a predetermined length profile of at least one of the first and second comb fingers.

12. The capacitive actuator according to claim 7, wherein the geometry of the at least one of the first and second comb electrodes is optimized via a predetermined distance profile of at least one of the first and second comb fingers.
